(19) United States
(12) Patent Application Publication
(10) Pub. No.: US 2026/0056231 A1
(43) Pub. Date: Feb. 26, 2026

(54) POGO PIN AND TEST SOCKET INCLUDING THE SAME

(71) Applicant: TSE CO., LTD., Chungcheongnam-do (KR)

(72) Inventors: Yee Sun Kang, Chungcheongnam-do (KR); Su Hyun Jeong, Chungcheongnam-do (KR)

(21) Appl. No.: 19/302,249

(22) Filed: Aug. 18, 2025

(30) Foreign Application Priority Data
Aug. 20, 2024 (KR) 10-2024-0111551

(51) Int. Cl. G01R 1/067; G01R 1/04

(52) U.S. Cl. CPC G01R 1/06722; G01R 1/0408; G01R 1/06755

(57) ABSTRACT

A lower plunger of a pogo pin according to the present disclosure includes a metal pin and an electro-conductive rubber, and the electro-conductive rubber having a configuration in which a plurality of electro-conductive particles are contained in an elastic insulating material is attached to a lower end of the metal pin to increase a contact area between the lower plunger and a pad of a test board through a surface contact, thereby preventing the occurrence of inductive spikes and thus improving signal quality in a high-speed signal transmission environment.

### CROSS-REFERENCE TO RELATED APPLICATION

This application claims priority of Korean Patent Application No. 10-2024-0111551, filed on August 20, 2024 , in the KIPO (Korean Intellectual Property Office), the disclosure of which is incorporated herein entirely by reference.

### BACKGROUND OF THE INVENTION

### FIELD OF THE INVENTION

The present disclosure relates to a pogo pin, and more particularly, to a pogo pin used for electrically testing a device under test, and a test socket including the same.

### DESCRIPTION OF THE RELATED ART

A device (e.g. a semiconductor package) under test has densely integrated electronic circuits formed thereon, and during the manufacturing process, undergoes a test process to identify whether each electronic circuit is operating normally. A test process is the process for testing the device under test to determine whether it is operating normally, and for sorting it as either good device or defective device based on the test results.

The process for testing the device under test utilizes a tester configured to electrically connect terminals of the device under test and a test board applying a test signal. The test board has various structures depending on the type of device under test to be tested. The test board and the device under test are not directly connected to each other, but indirectly connected to each other through a test socket.

A pogo socket is a test socket in which a pogo pin electrically connect a terminal of a device under test and a pad of a test board.

FIG. 1 is a view depicting a pogo socket type-test socket utilizing a conventional pin, and FIG. 2 is an enlarged view of the socket pin.

As shown in FIGS. 1 and 2, a test socket 50 is formed by disposing pogo pins 30 in pin holes 43, one by one, which are formed in a lower cover 42 and an upper cover 41. In the test socket, an upper plunger 32 of the pogo pin 30 is placed such that it is electrically connected to a terminal 11 of a device 10 under test, and a lower plunger 33 is placed such that it is electrically connected to a pad of a test board 20. In this state, an electrical test for the device under test may be performed using the test socket.

The conventional pogo pin 30 is configured such that the upper plunger 32 (which will be connected to the device under test) and the lower plunger 33 (which will be connected to the test board) are disposed at upper and lower portions of a barrel 31, respectively, and a spring 34 is interposed between the upper and lower plungers. Due to this configuration, the pogo pin has its own elasticity. A plurality of tip sections may be provided on an upper side of the upper plunger 32 to improve contact efficiency between the terminal 11 of the device under test and the upper plunger.

In the pogo pin 30, an upper end 35 and a lower end 36 of the cylindrical barrel are caulked and assembled to prevent the upper plunger 32 and the lower plunger 33 from being detached from the barrel 31. An electrical connection of this pogo pin 30 is preferably formed between the upper plunger, the lower plunger and barrel, so the pogo pin is formed of an electro-conductive material, such as a copper alloy coated with gold, or the like.

The pogo socket-type test socket 50 is the test socket which has been used for a long time and has strong mechanical durability, and the pogo pin is manufactured via individual and mechanical machining, so this test socket is advantageous for precise testing of light, thin and compact semiconductor packages.

However, the pogo socket-type test socket 50 has the problem of generating inductive spikes in high-speed signal transmission environments. Inductive spikes are voltage spikes caused by a drastic change in impedance, and are primarily found in circuits including inductance.

As shown in FIG. 3, for the pogo socket-type test socket, from the results of measuring impedance (Y-axis) measured in a signal path and a distance (X-axis) traveled by a transmission signal (X-axis), it can be seen that a drastic change in impedance occurred in a region indicated by the dotted line. Considering the signal transmission distance, this region is identified as a region where the pogo pin and the pad of the test board is in contact with each other.

Since a lower end portion of the lower plunger of the pogo pin that makes contact with the pad of the test board is designed to have a sharp angled shape in order to improve the contact between the pogo pin and the pad of the test board, impedance in a section where the pogo pin and the pad of the test board come into contact with each other is drastically changed.

Here, the pogo pin having the sharpened and angular shaped lower plunger of the pogo pin results from the fact that, as compared with a cylindrical conductor, a cross-sectional area thereof through which current passes is dramatically reduced.

Therefore, the test socket having the conventional pogo pin had a problem in that because the contact area between the pogo pin and the pad of the test board is small, a reflection loss is increased due to the occurrence of inductive spikes causing a drastic change in impedance at the contact point, thereby degrading signal quality in high-speed signal transmission environments.

### SUMMARY OF THE INVENTION

The present disclosure is conceived in light of the above-described drawbacks, and an object of the present disclosure is to provide a pogo pin that is advantageous for high-speed signal transmission by having an improved structure that allows it to come into face-contact with a pad of a test board, and a test socket including the same.

In order to achieve the above object, a pogo pin according to the present disclosure is a pogo pin for electrically connecting a terminal of a device under test and a pad of a test board, and may include a cylindrical barrel; an upper plunger configured to be moved upward/downward through an upper opening of the barrel to come into contact with the terminal of the device under test; a lower plunger configured to be moved upward/downward through a lower opening of the barrel to come into contact with the pad of the test board; and a spring configured to apply an elastic force to the upper plunger and the lower plunger in a direction away from each other within the barrel, wherein the lower plunger may include a metal pin and an electro-conductive rubber attached to a lower end of the metal pin and coming into surface-contact with an upper surface of the pad, and the electro-conductive rubber may have a structure in which a plurality of electro-conductive particles are contained within an elastic insulating material.

A width of the electro-conductive rubber may be equal to or larger than a width of a lower surface of the metal pin.

The electro-conductive rubber may be attached to a lower surface of the metal pin by an adhesive.

A lower surface of the lower plunger may have a flat shape, a concave recess may be formed in a central portion of the lower surface, and the electro-conductive rubber may be attached to both the recess and the lower surface.

Also, in order to achieve the above object, a test socket according to the present disclosure is a test socket for electrically connecting terminals of a device under test and pads of the test board, and may include a housing having a plurality of pin holes formed therein to correspond to the terminals, respectively, and pogo pins defined as above, each pogo pin being disposed in the pin hole.

In addition, a test socket according to the present disclosure is a test socket for electrically connecting terminals of a device under test and pads of the test board, and may include an elastic electro-conductive sheet mounted above the test board and including a support film and a plurality of electro-conductive parts formed in the support film, the support film being configured to electrically insulate and support the electro-conductive parts and each of the electro-conductive parts corresponding to each pad and being formed of a plurality of electro-conductive particles contained in an elastic insulating material, a housing disposed above the elastic-conductive sheet and having a plurality of pin holes formed therein to correspond to the electro-conductive parts, respectively, and pogo pins disposed in the pin holes, respectively. Here, each of the pogo pins may include a cylindrical barrel, an upper plunger configured to be moved upward/downward through an upper opening of the barrel to come into contact with the terminal of the device under test, a lower plunger configured to be moved upward/downward through a lower opening of the barrel to come into contact with the pad of the test board, and a spring configured to apply an elastic force to the upper plunger and the lower plunger in a direction away from each other within the barrel, and the lower plunger may have a flat lower surface, and the lower surface of the lower plunger comes into surface-contact with an upper surface of the electro-conductive part.

A width of the electro-conductive part may be equal to or the same as a width of a lower surface of the lower plunger.

The support film may be made of a polyimide material.

In the test socket provided with the pogo pin according to the present disclosure, since the electro-conductive rubber of the lower plunger comes into surface-contact with the pad of the test board, a contact area between the lower plunger and the pad of the test board is increased to reduce the effect of inductive reactance, so the amount of impedance change at the contact point is reduced, which can improve signal quality in a high-speed signal transmission environment.

Also, in the test socket provided with the pogo pin according to the present disclosure, since the pad of the test board and the electro-conductive rubber of the lower plunger come into surface-contact with each other, even if the pogo pin and the pad of the test board are slightly out of alignment, the phenomenon of poor contact is significantly reduced due to a sufficient contact area.

Furthermore, in the pogo pin according to the present disclosure, since the lower plunger has a configuration in which the electro-conductive rubber is attached to the lower surface of the metal pin, if the electro-conductive rubber of the lower plunger is damaged during numerous test processes, it is possible to remove the damaged electro-conductive rubber and replace it quickly and easily with a pre-formed electro-conductive rubber.

In the test socket provided with the pogo pin according to the present disclosure, since the lower plunger composed of the metal pin is electrically connected to the pad of the test board through the electro-conductive part of the elastic electro-conductive sheet, a contact area between the lower plunger and the electro-conductive part of the elastic electro-conductive sheet can be increased by a surface-contact, reducing the size of inductive spikes caused by insufficient contact area and thus improving signal quality in high-speed signal transmission environments. In addition, the process of attaching the electro-conductive rubber to the lower plunger can be omitted to greatly reduce the test setup time.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 is a view depicting a test apparatus using a conventional pogo socket;

FIG. 2 is a view depicting a state in which a conventional pogo pin comes into contact with a pad of a test board;

FIG. 3 is a graph showing a change in impedance depending on a signal transmission length of the conventional pogo pin;

FIG. 4 depicts a cross-sectional view and an exploded perspective view of a pogo pin according to one embodiment of the present disclosure;

FIG. 5 is a view depicting a disassembled state of part “A” of FIG. 4;

FIG. 6 is a view depicting a test apparatus using the pogo pin according to one embodiment of the present disclosure;

FIG. 7 is a view depicting a state in which a pogo pin according to one embodiment of the present disclosure comes into contact with a pad of a test board;

FIG. 8 is a cross-sectional view of a pogo pin according to another embodiment of the present disclosure; and

FIG. 9 is a view depicting a test apparatus using the pogo pin according to another embodiment of the disclosure.

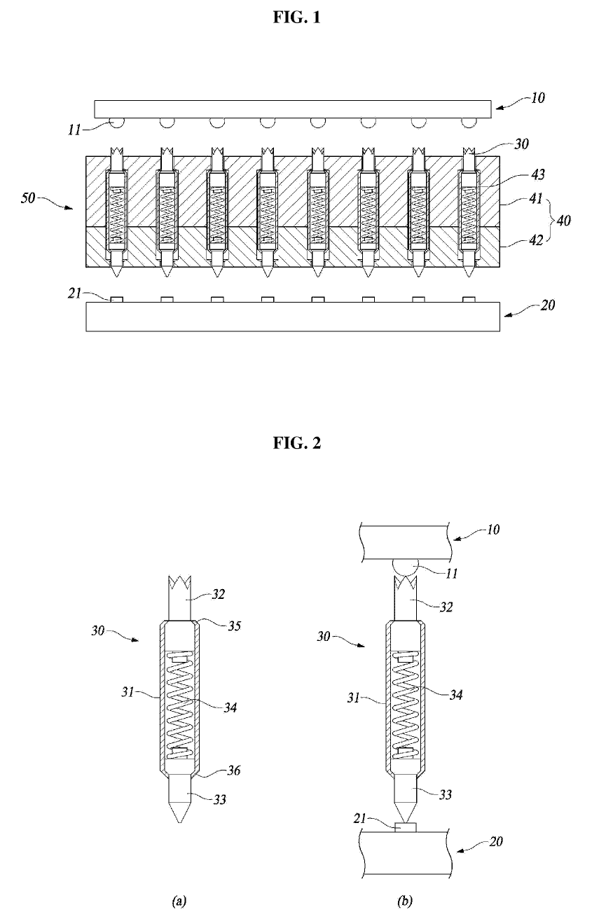

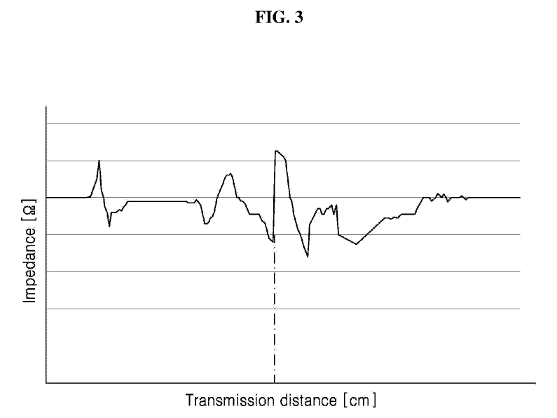

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms "a", "an" and "the" are intended to include the plural forms as well, unless the context clearly indicates otherwise. It will be further understood that the terms “includes”, "comprises" and/or "comprising," when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed "on" a substrate or other layer refers to a layer formed directly on top of the substrate or other layer or to an intermediate layer or intermediate layers formed on the substrate or other layer. It will also be understood by those skilled in the art that structures or shapes that are "adjacent" to other structures or shapes may have portions that overlap or are disposed below the adjacent features.

In this specification, the relative terms, such as "below", "above", "upper", "lower", "horizontal", and "vertical", may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

Hereinafter, a pogo pin and according to the present disclosure a test socket including the same will be described in detail with reference to the drawings.

In the present disclosure, a device under test is placed above a test socket, and a test board is placed below the test socket, so an “upper surface”, “an upper side”, “an upper end”, “a lower surface”, “a lower side”, “a lower end”, and the like of any component are described on the basis of the above. In addition, the same or similar components are labeled with the same or similar reference numbers, and a description thereon is omitted.

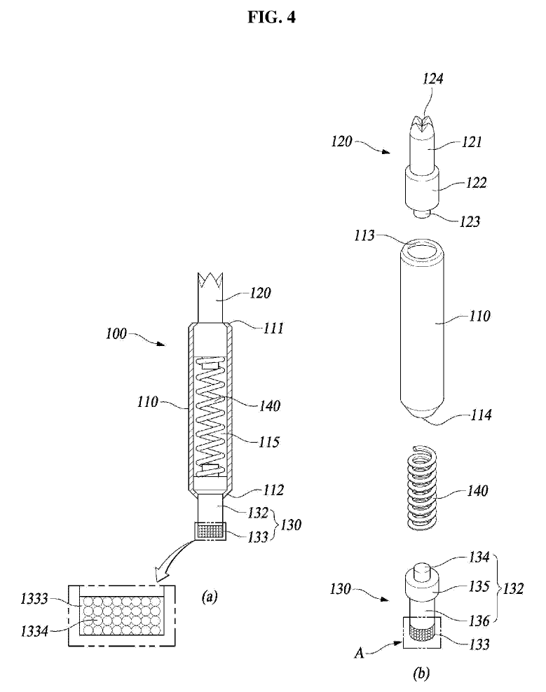

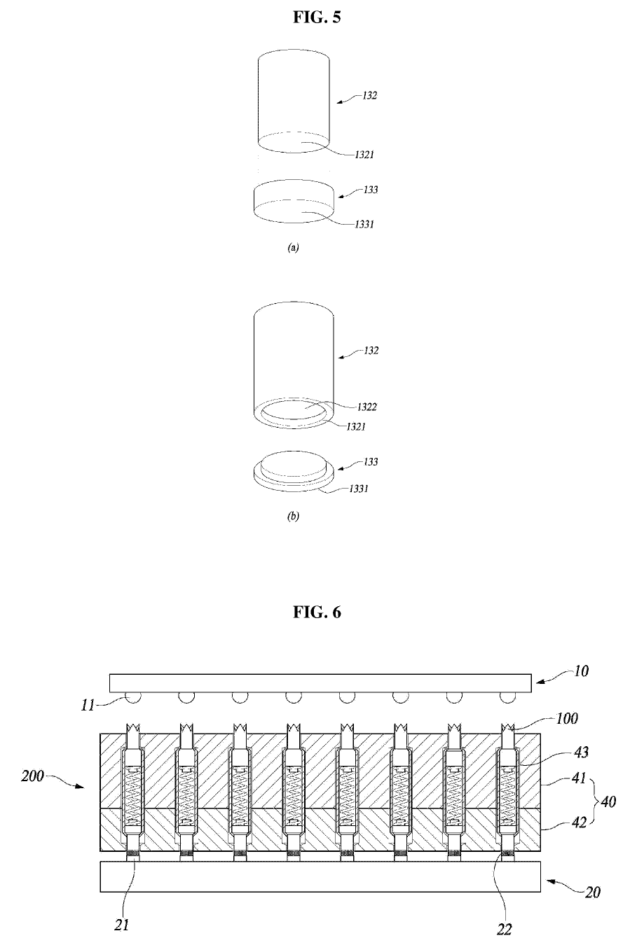

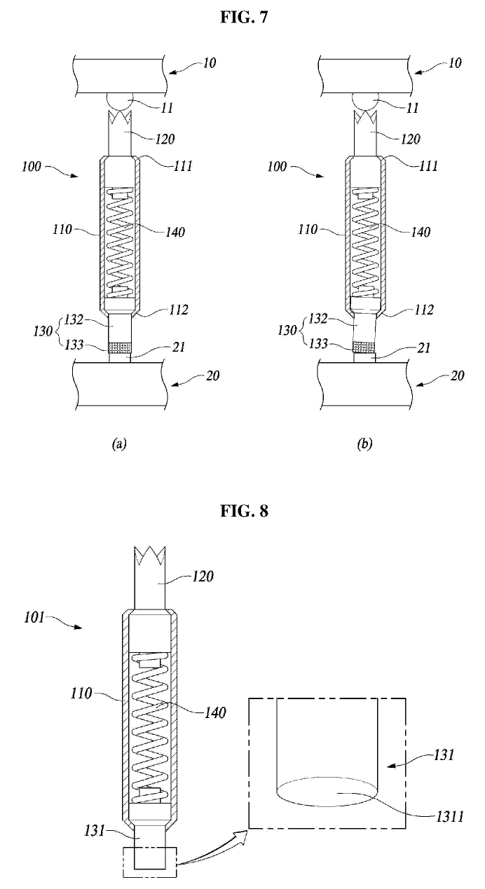

FIG. 4 depicts a cross-sectional view and an exploded perspective view of a pogo pin according to one embodiment of the present disclosure, FIG. 5 is a view depicting a disassembled state of part “A” of FIG. 4(b), FIG. 6 is a view depicting a test apparatus using the pogo pin according to one embodiment of the present disclosure, and FIG. 7 is a view depicting a state in which a pogo pin according to one embodiment of the present disclosure comes into contact with a pad of a test board.

As illustrated in the drawings, a test socket 200 according to one embodiment of the present disclosure is a socket configured to connect a terminal 11 of a device 10 under test to a pad 21 of a test board 20 generating a test signal, thereby performing an electrical test on the device 10 under test. The test socket 200 includes a housing 40 having pin holes 43 formed therein, and pogo pins 100 disposed in the pin holes, respectively.

As shown in FIG. 6, the housing 40 forms a body of the test socket 200, and the pogo pins 100 which are mounted at positions corresponding to the terminals 11 of the device under test are coupled to and supported by an upper cover 41 and a lower cover 42. The housing 40 the has pin holes 43 into which the pogo pins 100 are inserted, respectively, and each pin hole is formed to penetrate the housing 40 in a thickness direction, i.e., in a vertical direction. The housing has a configuration that is not significantly different from a conventional configuration, so a detailed description thereon is omitted.

As shown in FIGS. 4 to 6, the pogo pin 100 according to the present disclosure may be supported by the housing 40 to electrically connect the terminal 11 of the device 10 under test and the pad 21 of the test board 20.

The pogo pin 100 includes a cylindrical barrel 110, an upper plunger 120 that is moved upward/downward through an upper opening 113 in the barrel to come into contact with the terminal 11 of the device under test, a lower plunger 130 that is moved upward/downward through a lower opening 114 in the barrel to come into contact with the pad 21 of the test board, and a spring 140 configured to apply an elastic force to the upper plunger and the lower plunger in a direction away from each other within the barrel. Here, the lower plunger 130 may include a metal pin 132 and an electro-conductive rubber 133 that is attached to a lower end of the metal pin 132 and comes into contact with an upper surface 22 of the pad 21 of the test board, and the electro-conductive rubber has a structure in which a plurality of electro-conductive particles 1334 are contained within an elastic insulating material 1333.

The barrel 110 is formed into a cylindrical shape to have a space 115 formed therein. The upper plunger 120, the spring 140, and the lower plunger 130 are received in the internal space 115. An upper end 111 and a lower end 112 of the barrel 110 are caulked and assembled to prevent the upper plunger 120 and the lower plunger 130 from being detached from the barrel 110. The upper opening 113 is formed in an upper side of the barrel, and the lower opening 114 is formed in a lower side of the barrel. Since upper and lower ends of the barrel are caulked, the upper opening 113 and lower opening 114 are formed to have a width smaller than a width of the space.

The upper plunger 120 is housed inside the barrel 110, and a portion thereof may protrude from the upper end of the barrel 110 through the upper opening 113 to be connected to the terminal 11 of the device 10 under test.

The upper plunger 120 includes an upper head part 122, a first contact part 121 extending from an upper end of the upper head part 122 such that it may pass through the upper opening 113, and a second contact part 123 extending from a lower end of the upper head part 122. A width of the upper head part 122 is equal to or slightly smaller than a width of the space 115 of the barrel 110. Due to this configuration, the upper head part 122 cannot pass through the upper opening 113 of the barrel 110 and may be moved in the space 115 of the barrel 110 in a longitudinal direction of the barrel 110. The first contact part 121 protrudes from the upper end of the barrel 110, so its end may be connected to the terminal 11 of the device 10 under test. A plurality of tip sections 124 may be provided on an upper side of the first contact part 121 to improve contact efficiency between the terminal 11 of the device under test and the first contact part. The second contact part 123 is inserted into the spring 140 inside the barrel to make contact with the spring. A specific configuration of the upper plunger 120 is not limited to that shown in the drawings, and may be variously altered.

The upper plunger 120 may be made of a ferromagnetic metal such as iron, nickel, cobalt, or an alloy thereof, or a metal such as a gold-coated copper alloy. Preferably, the upper plunger is made of a ferromagnetic metal.

The spring 140 may be received inside the barrel 110 to apply an elastic force to the upper plunger 120 and lower plunger 130. One end of the spring 140 is in contact with the upper plunger 120, and the other end contacts the lower plunger 130. Due to the above configuration, the upper plunger 120 and the lower plunger 30 are in direct contact with the spring 140, and may thus receive the elastic force of the spring 140 directly.

The lower plunger 130 is received inside the barrel 110, but a portion thereof protrudes from the lower end of the barrel 110 through the lower opening 114, so it may be connected to the pad 21 of the test board 20. The lower plunger 130 includes the metal pin 132 and the electro-conductive rubber 133.

The metal pin 132 includes a lower head part 135, a third contact part 136 extending from a lower end of the lower head part 135 such that it may pass through the lower opening 114 of the barrel 110, and a fourth contact part 134 extending from an upper end of the lower head part 135. A width of the lower head part 135 is equal to or slightly smaller than a width of the space 115 of the barrel 110. The lower head part 135 may be formed to have a width that is equal to a width of the upper head part 122. Therefore, the lower head part 135 cannot pass through the lower opening 114 of the barrel 110, and may be moved in the space 115 of the barrel 110 in the longitudinal direction of the barrel 110. The third contact part 136 protrudes from the lower end of the barrel 110, and the electro-conductive rubber 133 is attached to a lower surface thereof. The electro-conductive rubber 133 attached to the third contact part 136 may be connected to the pad 21 of the test board 20. The fourth contact portion 134 is inserted into the spring 140 within the barrel and makes contact with the spring.

A material used for forming the metal pin 132 of the lower plunger 130 may be the same as that used for forming the upper plunger 120.

The electro-conductive rubber 133 is attached to the lower end of the metal pin 132, i.e., a lower end of the third contact part 136. The lower end of this metal pin 132 may have a flat shaped lower surface 1321, as shown in (a) of FIG. 5.

As shown in (a) of FIG. 4, the electro-conductive rubber 133 is fabricated in a configuration in which a plurality of electro-conductive particles 1334 are included in an elastic insulating material 1333. When this electro-conductive rubber 133 is compressed, the electro-conductive particles come into contact with each other to form a electro-conductive path. It is more preferable for the electro-conductive rubber 133 to be formed by aligning a number of electro-conductive particles contained in the elastic insulating material in the vertical direction (i.e., in a thickness direction of the electro-conductive rubber) using a magnetic field and then hardening the particles.

As an elastic insulating material 1333 constituting the electro-conductive rubber 133, a heat-resistant polymer material having a crosslinked structure, for example, silicone rubber, polybutadiene rubber, natural rubber, polyisoprene rubber, styrene-butadiene copolymer rubber, acrylonitrile-butadiene copolymer rubber, styrene-butadiene-diene block copolymer rubber, styrene-isoprene block copolymer rubber, urethane rubber, polyester rubber, epichlorohydrin rubber, ethylene-propylene copolymer rubber, ethylene-propylene-diene copolymer rubber, soft liquid epoxy rubber, and the like may be employed.

In addition, as the electro-conductive particles 1334 constituting the electro-conductive rubber 133, the particles having magnetism may be employed such that they may be reacted by a magnetic field. For example, as the electro-conductive particles, particles obtained by plating a surface of core particles, for example, particles of metal exhibiting magnetism, such as iron, nickel, cobalt, etc., or alloy particles thereof, or particles containing these metals, or particles of these metals, with a metal having excellent electrical-conductivity, such as gold, silver, palladium, radium, or the like; particles obtained by plating a surface of core particles, for example, non-magnetic metal particles, inorganic substance particles such as glass beads or the like, and polymer particles, with electro-conductive magnetic substance such as nickel, cobalt, or the like; or particles obtained by plating core particles with electro-conductive magnetic substance and a metal having excellent electrical-conductivity may be employed.

The lower plunger 130 is completed by attaching the electro-conductive rubber 133 to a lower end of the metal pin 132. The electro-conductive rubber 133 may be attached to the metal pin 132 using an adhesive. It is desirable to utilize substance that guarantees heat resistance and durability while maintaining electro-conductivity as the adhesive.

As shown in (b) of FIG. 5 (b), the lower surface 1321 of the metal pin 132 is formed into a flat shape, and a concave recess 1322 facing inward of the metal pin is formed in a central portion of the lower surface 1321 of the metal pin to allow the lower surface to have a stepped portion. Furthermore, the electro-conductive rubber 133 is formed to have a corresponding shape that is coupled with the lower surface 1321 of the metal pin 132 having the concave recess 1322. This allows the electro-conductive rubber 133 to be attached to both the lower surface 1321 and the concave recess 1322 of the metal pin, thereby allowing the metal pin 132 and the electro-conductive rubber 133 to be more securely attached to each other. If an attachment area between the lower surface of the metal pin and the electro-conductive rubber is increased to allow the electro-conductive rubber to be securely attached to the metal pin, the metal pin and the electro-conductive rubber can be engaged with each other using other shapes, for example using toothed parts or concave-convex parts formed on the lower surface of the metal pin and the electro-conductive rubber, or can be coupled to each other using step-shaped parts formed thereon.

In addition, rather than attaching the electro-conductive rubber to the metal pin, the electro-conductive rubber and the metal pin may be coupled to each other by forming a portion of the electro-conductive rubber corresponding to the concave recess 1332 of the metal pin to have a diameter slightly larger than a diameter of the concave recess and by forcibly fitting this portion of the electro-conductive rubber into the concave recess of the metal pin.

The electro-conductive rubber 133 may be formed to have a width that is equal to or slightly larger than a width of the lower surface 1321 of the metal pin 132. (a) of FIG. 5 depicts an example in which a width of the electro-conductive rubber is slightly larger than a width of the lower surface of the metal pin. The electro-conductive rubber that is slightly larger than a width of the lower surface of the metal pin may correspond to the entire lower surface of the fine metal pin, enabling it to be completely attached to the lower surface of the metal pin even if positional errors occur during an attachment process.

As shown in FIGS. 6 and 7, the test socket 200 is mounted on the test board 20 such that the plurality of pogo pins 100 are connected to the plurality of pads 21 provided on the test board 20. During a test process for the device 10 under test, if the test device 10 is pushed toward the test socket 200 by a pressurizing means such as a pusher and the terminal 11 of the device 10 under pressurizes an upper side of the upper plunger 120, the spring 140 is compressed by the pressure applied to the upper plunger 120, and due to the elastic force of the spring 140, the lower plunger 130 then compresses the pad 21 of the test board 20. At this time, the electro-conductive rubber is compressed while the lower surface 1331 of the electro-conductive rubber 133 of the lower plunger 130 comes into surface-contact with the upper surface 22 of the pad 21 of the test board. When the electro-conductive rubber 133 is compressed, multiple electro-conductive particles come into contact with each other, so the electric may flow through electro-conductive rubber 133, thereby forming an electrical path through the upper plunger 120, barrel 110, and lower plunger 130. Consequently, the terminals 11 of the device 10 under test are electrically connected to the pads 21 of the test board 20 through the pogo pins 100, respectively. At this time, a test signal generated by the test board 20 is transmitted to the device 10 under test through the pogo pins 100 to enable an electrical test for the device 10 under test to be performed.

As described above, in the test socket 200 equipped with the pogo pin 100 according to one embodiment of the present disclosure, the electro-conductive rubber 133 of the lower plunger 130 comes into surface-contact with the pad 21 of the test board. Therefore, the contact area between the lower plunger and the pad of the test board is increased, reducing the influence of inductive reactance. As a result, the change in impedance at the contact point is decreased, thereby improving signal quality in high-speed signal transmission environments.

In addition, in the process of pressurizing the pogo pin 100, a tilting phenomenon in which the pogo pin, the terminal of the device under test and the pad of the test board are slightly out of alignment may occur. This tilting phenomenon occurs mainly in the lower plunger 130. In the lower plunger 130 constituting the pogo pin 100 of the present disclosure, as shown in FIG. 7(b), since the electro-conductive rubber 133 is attached to a lower surface of the metal pin 132 and the electro-conductive rubber has elasticity and can be compressed, even if the lower plunger is tilted, it can come into surface-contact with the pad 21 of the test board through the electro-conductive rubber. Therefore, even if the alignment of the pogo pin is disrupted due to the tilting phenomenon, the pogo pin may be stably connected to the pad of the test board without poor contact therebetween.

In addition, since the lower plunger 130 has a configuration in which the electro-conductive rubber 133 is attached to the lower surface of the metal pin 132, if the electro-conductive rubber of the lower plunger is damaged during numerous test processes, it is possible to remove the damaged electro-conductive rubber and replace it quickly and easily with a pre-formed electro-conductive rubber.

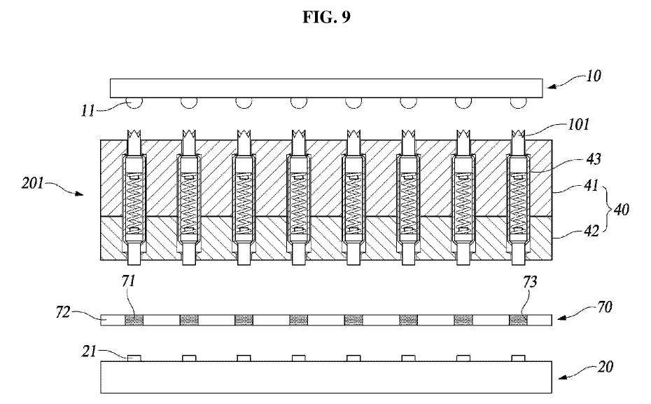

FIGS. 8 and 9 illustrate a pogo pin 101 according to another embodiment of the present disclosure, and a test apparatus utilizing a test socket 201 equipped with this pogo pin.

As shown in the drawings, the test socket 201 according to another embodiment of the present disclosure includes an elastic electro-conductive sheet 70 including a support film 72 and a plurality of electro-conductive parts 71 formed in the support film 72, the housing 40 disposed above the elastic electro-conductive sheet 70 and having pin holes 43 which are formed therein and correspond to the electro-conductive parts 71, respectively, and the pogo pins 101 disposed in the pin holes 43, respectively.

The elastic electro-conductive sheet 70 is mounted above the test board 20, and the electro-conductive parts 71 correspond the pads 21 of the test board, respectively. The support film 72 is configured to electrically insulate and support the electro-conductive parts 71. Each of the electro-conductive parts 71 is formed of a plurality of electro-conductive particles contained in an elastic insulating material.

In addition, the pogo pin 101 includes the cylindrical barrel 110, the upper plunger 120 that is moved upward/downward through the upper opening of the barrel to come into contact with the terminal of the device under test, a lower plunger 131 that is moved upward/downward through the lower opening of the barrel to come into contact with the electro-conductive part 71 of the elastic electro-conductive sheet 70, and the spring 140 configured to apply an elastic force to the upper plunger and the lower plunger in a direction away from each other within the barrel. Here, the lower plunger 131 has a flat lower surface 1311, and this lower surface of the lower plunger comes into surface-contact with an upper surface of the electro-conductive part 71.

As compared with the test socket 200 according to one embodiment of the present disclosure, the test socket 201 according to another embodiment of the present disclosure differs from the test socket 200 in that the lower plunger 131 is comprised solely of the metal pin to which no electro-conductive rubber is attached, and that the elastic electro-conductive sheet 70 is mounted above the test board 20.

The lower plunger 131 is comprised of the metal pin, and the lower surface 1311 thereof may be formed in a flat shape.

The elastic electro-conductive sheet 70 may include the plurality of electro-conductive parts 71 disposed to correspond the pads 21 of the test board, respectively, and formed of the plurality electro-conductive particles contained in the elastic insulating material, and the support film 72 configured to electrically insulate and support the electro-conductive parts 71. The support film 72 may be made of a polyimide material.

The elastic electro-conductive sheet 70 may be manufactured by a method of forming the electro-conductive parts 71 including forming through holes 73 using a laser or the like at locations of a support film 72, which corresponds to the pads of the test board, respectively, filling the through holes with an elastic insulating material containing a plurality of electro-conductive particles, and curing the elastic insulating material. Of course, it is also possible to align the plurality of electro-conductive particles in the vertical direction by applying a magnetic field to the elastic insulating material containing the plurality of electro-conductive particles before curing it.

The electro-conductive part 71 of the elastic electro-conductive sheet may be formed to have a width that is equal to or slightly larger than a width of the lower surface 1311 of the lower plunger 131. FIG. 9 depicts an example in which a width of the electro-conductive part is slightly larger than a width of the lower surface of the lower plunger. The electro-conductive part 73 having a width slightly larger than a width of the lower surface of the lower plunger enables the lower plunger of the pogo pin to be easily connected to the pad 21 of the test board.

In the test socket 201 according to another embodiment of the present disclosure, since the elastic electro-conductive sheet 70 having the electro-conductive parts 71 is disposed above the test board 20, the lower surface 1311 of the lower plunger 131 of the pogo pin 101 comes into face-contact with an upper surface of the corresponding electro-conductive part 71 of the elastic electro-conductive sheet and an lower surface of the electro-conductive part 71 of the elastic electro-conductive sheet comes into face-contact with the corresponding pad 21 of the test board. As a result, a contact area between the pogo pin 101 and the electro-conductive part 71 of the elastic electro-conductive sheet 70 may be increased, and this reduces the magnitude of inductive spikes caused by insufficient contact area, thereby improving signal quality in a high-speed signal transmission environment. In other words, the test socket of this embodiment can achieve effects that are almost identical to those obtained by the test socket according to the previous embodiment.

Furthermore, the test socket 101 according to another embodiment of the present disclosure can omit the process of attaching the electro-conductive rubbers to the lower plungers 131 one by one, thereby greatly reducing the test setup time.

Although the present disclosure has been described with reference to preferred embodiments, the scope of the present disclosure is not limited to the previously described and illustrated forms.

The drawings illustrate that the device 10 under test to be tested using the test socket according to the present disclosure is described as having a ball grid array (BGA) terminals 11 using solder balls, the test socket 200 according to the present disclosure may also be applied to the device under test equipped with planar terminals such as land grid array (LGA) terminals or the like.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims. The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A pogo pin for electrically connecting a terminal of a device under test and a pad of a test board, comprising:
a cylindrical barrel; an upper plunger configured to be moved upward/downward through an upper opening of the barrel to come into contact with the terminal of the device under test; a lower plunger configured to be moved upward/downward through a lower opening of the barrel to come into contact with the pad of the test board; and a spring configured to apply an elastic force to the upper plunger and the lower plunger in a direction away from each other within the barrel, wherein the lower plunger comprises a metal pin and an electro-conductive rubber attached to a lower end of the metal pin and coming into surface-contact with an upper surface of the pad, and the electro-conductive rubber has a structure in which a plurality of electro-conductive particles are contained within an elastic insulating material.

2. The pogo pin of claim 1, wherein the electro-conductive rubber has a width that is equal to or larger than a width of a lower surface of the metal pin.

3. The pogo pin of claim 1, wherein the electro-conductive rubber is attached to a lower surface of the metal pin by an adhesive.

4. The pogo pin of claim 3, wherein a lower surface of the lower plunger has a flat shape, a concave recess is formed in a central portion of the lower surface, and the electro-conductive rubber is attached to both the recess and the lower surface.

5. A test socket for electrically connecting terminals of a device under test and pads of the test board, comprising:
a housing having a plurality of pin holes formed therein to correspond to the terminals, respectively; and pogo pins according to claim 1, each pogo pin being disposed in the pin hole.

6. A test socket for electrically connecting terminals of a device under test and pads of the test board, comprising:
an elastic electro-conductive sheet mounted above the test board and comprising a support film and a plurality of electro-conductive parts formed in the support film, the support film being configured to electrically insulate and support the electro-conductive parts and each of the electro-conductive parts corresponding to each pad and being formed of a plurality of electro-conductive particles contained in an elastic insulating material;
a housing disposed above the elastic-conductive sheet, and having a plurality of pin holes formed therein and corresponding to the electro-conductive parts, respectively; and pogo pins disposed in the pin holes, respectively, wherein each of the pogo pins comprises a cylindrical barrel, an upper plunger configured to be moved upward/downward through an upper opening of the barrel to come into contact with the terminal of the device under test, a lower plunger configured to be moved upward/downward through a lower opening of the barrel to come into contact with the pad of the test board, and a spring configured to apply an elastic force to the upper plunger and the lower plunger in a direction away from each other within the barrel, wherein the lower plunger has a flat lower surface, and the lower surface of the lower plunger comes into surface-contact with an upper surface of the electro-conductive part.

7. The test socket of claim 6, wherein the electro-conductive part has a width that is equal to or the same as a width of a lower surface of the lower plunger.

8. The test socket of claim 6, wherein the support film is made of a polyimide material.
